(19) United States
(12) Patent Application Publication
(10) Pub. No.: US 2024/0017351 A1
(43) Pub. Date: Jan. 18, 2024

(54) LASER BEAM ANNEALING APPARATUS AND METHOD OF MANUFACTURING DISPLAY APPARATUS BY USING THE SAME

(71) Applicant: SAMSUNG DISPLAY CO., LTD., Yongin-si (KR)

(72) Inventor: Kyongsik CHOI, Yongin-si (KR)

(21) Appl. No.: 18/144,329

(22) Filed: May 8, 2023

(30) Foreign Application Priority Data
Jul. 18, 2022 (KR) 10-2022-0088552

(51) Int. Cl. B23K 26/06; B23K 26/00

(52) U.S. Cl. CPC B23K 26/0665; B23K 26/0648; B23K 26/0643; B23K 26/0006

(57) ABSTRACT

A laser beam annealing apparatus includes a laser generator which generates a first incident laser beam and a second incident laser beam, a beam mixer arranged on optical paths of the first incident laser beam and the second incident laser beam and including an inversion module which vertically and horizontally inverts an image of a laser beam, a homogenizer arranged on an optical path of a laser beam having passed through the beam mixer, and a condenser lens arranged on an optical path of a laser beam having passed through the homogenizer. The laser beam having passed through the beam mixer includes a first mixed beam in which an image is not inverted and a second mixed beam in which an image is vertically and horizontally inverted.

This application claims priority to Korean Patent Application No. 10-2022-0088552, filed on Jul. 18, 2022, and all the benefits accruing therefrom under 35 U.S.C. § 119, the content of which in its entirety is herein incorporated by reference.

### BACKGROUND

### 1. Field

Embodiments relate to a laser beam annealing apparatus and a method of manufacturing a display apparatus by the same, and more particularly, to a laser beam annealing apparatus capable of implementing a high-quality polysilicon layer and a method of manufacturing a display apparatus by the laser beam annealing apparatus.

### 2. Description of the Related Art

Generally, in a display apparatus, such as an organic light-emitting display apparatus, a plurality of thin-film transistors is formed on a substrate. The thin-film transistors may include a semiconductor layer, a source electrode, a drain electrode, and a gate electrode, and the semiconductor layer may include a polysilicon layer obtained by crystallizing an amorphous silicon layer.

In a manufacturing process of such a display apparatus, an amorphous silicon layer is crystallized to form a polysilicon layer, and to this end, a laser annealing method, in which an amorphous silicon layer is irradiated with a laser beam, is used.

### SUMMARY

Embodiments include a laser beam annealing apparatus capable of implementing a high-quality polysilicon layer and a method of manufacturing a display apparatus by the laser beam annealing apparatus. However, such an objective is only an example, and the scope of the disclosure is not limited thereto.

Additional features will be set forth in part in the description which follows and, in part, will be apparent from the description, or may be learned by practice of the presented embodiments of the disclosure.

In an embodiment of the disclosure, a laser beam annealing apparatus includes a laser generator which generates a first incident laser beam and a second incident laser beam, a beam mixer arranged on optical paths of the first incident laser beam and the second incident laser beam and including an inversion module which vertically and horizontally inverts an image of a laser beam, a homogenizer arranged on an optical path of a laser beam having passed through the beam mixer, and a condenser lens arranged on an optical path of a laser beam having passed through the homogenizer. The laser beam having passed through the beam mixer includes a first mixed beam in which an image is not inverted and a second mixed beam in which an image is vertically and horizontally inverted.

In an embodiment, the beam mixer may further include a splitter arranged at a front end of the inversion module.

In an embodiment, the inversion module may include a plurality of mirrors, at least one of the plurality of mirrors may vertically invert an image of a laser beam, and at least one of the plurality of mirrors may horizontally invert an image of a laser beam.

In an embodiment, the inversion module may include a first mirror, a second mirror, a third mirror, a fourth mirror, and a fifth mirror that are apart from each other and sequentially arranged along the optical path.

In an embodiment, a laser beam incident on the first mirror may be incident in a first direction, the second mirror may be arranged apart from the first mirror in a second direction perpendicular to the first direction, and a laser beam emitted through the fifth mirror may be emitted in a third direction perpendicular to the first and second directions.

In an embodiment, the inversion module may further include a circulation module which is arranged between the second mirror and the third mirror and increases the optical path.

In an embodiment, the inversion module may further include an optical member arranged between the second mirror and the third mirror.

In an embodiment, the optical member may include a polarizing plate.

In an embodiment, the third mirror and the fourth mirror may include moving mirrors.

In an embodiment, the inversion module may include a circulation module, an optical member, and a moving mirror, and the circulation module may increase the optical path.

In an embodiment of the disclosure, a method of manufacturing a display apparatus includes forming an amorphous silicon layer on a substrate, annealing the amorphous silicon layer on the substrate into a polysilicon layer by the laser beam annealing apparatus, forming a plurality of thin-film transistors by patterning the polysilicon layer, and forming display elements electrically and respectively connected to the plurality of thin-film transistors.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a diagram schematically illustrating an embodiment of a laser beam annealing apparatus;

FIG. 2 is a diagram schematically illustrating an embodiment of a configuration of an optical system of a laser beam annealing apparatus;

FIG. 3A is a diagram schematically illustrating an embodiment of a beam mixer in an optical system of a laser beam annealing apparatus;

FIG. 3B is a diagram illustrating an embodiment of a three-dimensional structure of a beam mixer;

FIG. 4 shows an embodiment of a beam mixer;

FIG. 5 shows an embodiment of a beam mixer;

FIG. 6 shows an embodiment of a beam mixer;

FIG. 7 shows an embodiment of a beam mixer; and

FIG. 8 is a cross-sectional view schematically illustrating an embodiment of a portion of a display apparatus manufactured according to a method for manufacturing a display apparatus.

### DETAILED DESCRIPTION

Reference will now be made in detail to embodiments, examples of which are illustrated in the accompanying drawings, where like reference numerals refer to like elements throughout. In this regard, the illustrative embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments of the disclosure will be described in detail with reference to the accompanying drawings. When describing embodiments with reference to the drawings, the same or corresponding components are denoted by the same reference numerals, and redundant descriptions thereof are omitted.

In the following embodiments, when various components such as layers, films, regions, plates, etc. are “on” other components, this includes not only a case where they are “on” other components, but also a case where another component is interposed therebetween. Sizes of components in the drawings may be exaggerated or reduced for convenience of explanation. For example, since sizes and thicknesses of components in the drawings are arbitrarily illustrated for convenience of explanation, the disclosure is not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

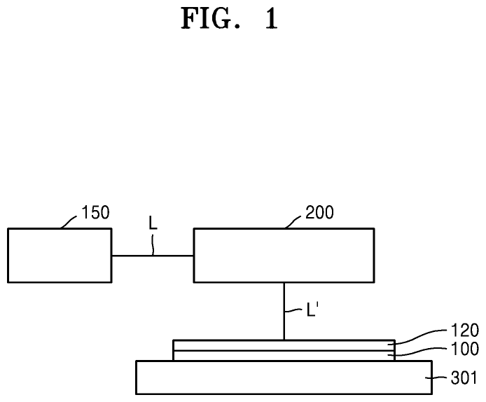

FIG. 1 is a diagram schematically illustrating an embodiment of a laser beam annealing apparatus.

Referring to FIG. 1, the laser beam annealing apparatus in an embodiment may include a laser generator 150 that generates an incident laser beam L, and an optical system 200 that optically converts the incident laser beam L to generate an output laser beam L′. In addition, the laser beam annealing apparatus may further include a stage 301 on which a target substrate 100 is disposed (e.g., mounted), and a target thin-film 120 to be laser-crystallized by irradiation with the output laser beam L′ may be disposed on the target substrate 100.

The incident laser beam L generated from the laser generator 150 is an excimer laser beam or the like that induces a phase change of the target thin-film 120, and may be converted into the output laser beam L′ to crystallize the target thin-film 120 formed or disposed on the target substrate 100. The target thin-film 120 may be an amorphous silicon layer, and the amorphous silicon layer may be formed by a method, such as low-pressure chemical vapor deposition, atmospheric pressure chemical vapor deposition, plasma enhanced chemical vapor deposition (“PECVD”), sputtering, or vacuum evaporation.

In the illustrated embodiment, the optical system 200 may include a beam mixer that vertically and horizontally inverts some images of the incident laser beam L and superimposes the images, and the beam mixer may include at least one mirror that fully reflects a laser beam. In addition, the beam mixer may include at least one splitter that reflects a portion of a laser beam and transmits the remaining portion of the laser beam.

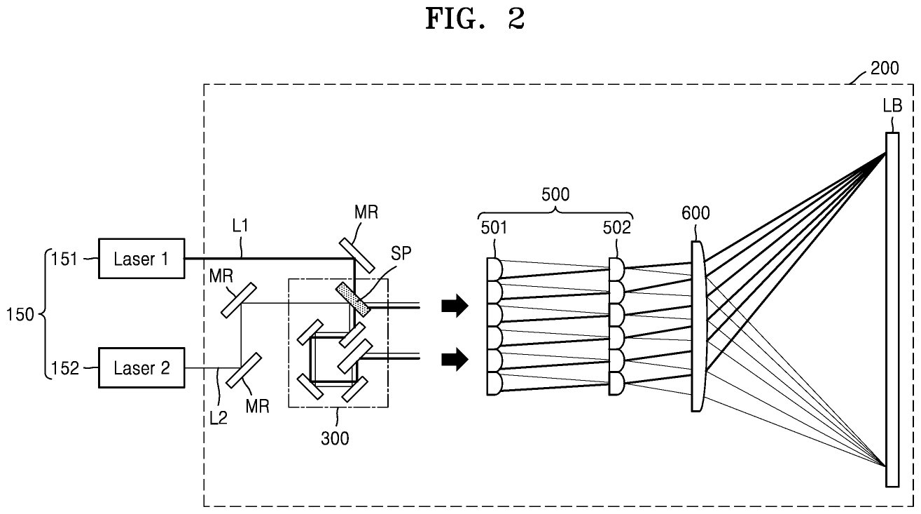

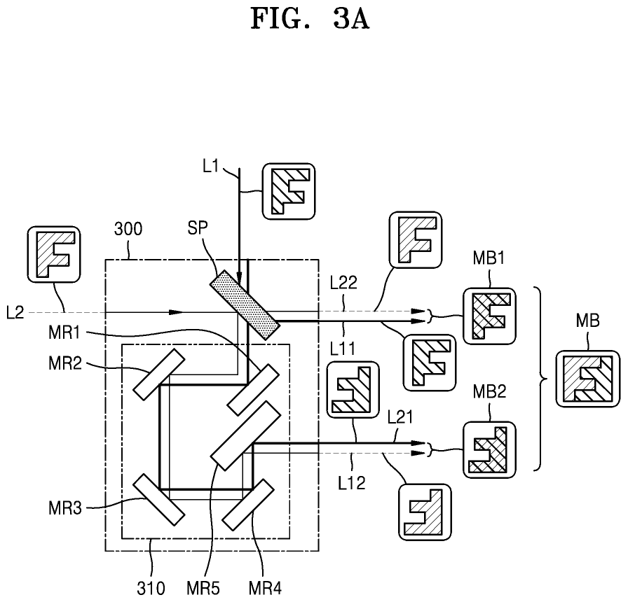

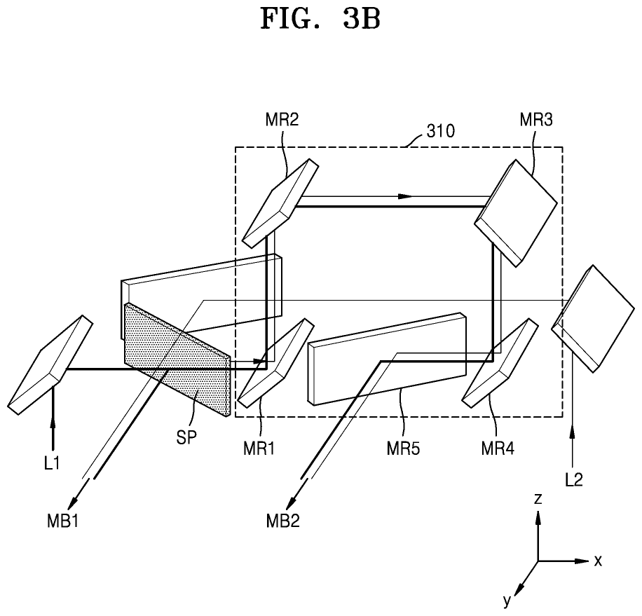

FIG. 2 is a diagram schematically illustrating an embodiment of a configuration of the optical system 200 of the laser beam annealing apparatus, FIG. 3A is a diagram schematically illustrating a beam mixer 300 in the optical system 200, and FIG. 3B is a diagram illustrating a three-dimensional structure of the beam mixer 300.

Referring to FIGS. 2 to 3B, the laser beam annealing apparatus may include the laser generator 150, the beam mixer 300, a homogenizer 500, and a condenser lens 600.

The laser generator 150 may include a first laser generator 151 and a second laser generator 152. The first laser generator 151 may generate a first incident laser beam L1, and the second laser generator 152 may generate a second incident laser beam L2.

Optical paths of the first incident laser beam L1 and the second incident laser beam L2 may be adjusted by a plurality of mirrors MR, such that the first incident laser beam L1 and the second incident laser beam L2 may be incident on the beam mixer 300.

The beam mixer 300 includes a splitter SP and an inversion module 310 that vertically and horizontally inverts an image of a laser beam. The inversion module 310 includes first to fifth mirrors MR1 to MR5 that reflect about 99% or more of a beam. The beam mixer 300 may form a first mixed beam MB1 in which an image of a laser beam is not inverted, and a second mixed beam MB2 in which an image of a laser beam is vertically and horizontally inverted.

The splitter SP may reflect a portion of an incident laser beam, and may transmit the remaining portion of the incident laser beam. In an embodiment, the first incident laser beam L1 may be incident on one surface of the splitter SP, about 50% of the first incident laser beam L1 may be reflected and proceed as a first reflected beam L11, and the remaining about 50% of the first incident laser beam L1 may be transmitted and proceed as a first transmitted beam L12, for example. The second incident laser beam L2 may be incident on the other surface of the splitter SP, about 50% of the second incident laser beam L2 may be reflected and proceed as a second reflected beam L21, and the remaining about 50% of the second incident laser beam L2 may be transmitted and proceed as a second transmitted beam L22.

Referring to FIG. 3A, the inversion module 310 may include the first mirror MR1, the second mirror MR2, the third mirror MR3, the fourth mirror MR4, and the fifth mirror MR5 that are apart from each other. At least one of the first to fifth mirrors MR1 to MR5 may be a mirror that vertically inverts an image of a laser beam, and at least one of the remaining mirrors may be a mirror that horizontally inverts an image of a laser beam.

The first mirror MR1, the second mirror MR2, the third mirror MR3, the fourth mirror MR4, and the fifth mirror MR5 may be sequentially arranged along an optical path. Reflective surfaces of the first mirror MR1 and the second mirror MR2 may face each other, and may be parallel to each other. Reflective surfaces of the second mirror MR2 and the third mirror MR3 may face each other, and the reflective surface of the third mirror MR3 may be inclined by about 90 degrees with respect to the reflective surface of the second mirror MR2. Reflective surfaces of the third mirror MR3 and the fourth mirror MR4 may face each other, and the reflective surface of the fourth mirror MR4 may be inclined by about 90 degrees with respect to the reflective surface of the third mirror MR3. The reflective surface of the fourth mirror MR4 may be parallel to the reflective surfaces of the first mirror MR1 and the second mirror MR2. The fifth mirror MR5 may face the fourth mirror MR4. The fifth mirror MR5 is a mirror for emitting the second mixed beam MB2 to the outside of the inversion module 310, and may adjust an optical path.

The first reflected beam L11 and the second transmitted beam L22 are laser beams that do not pass through the inversion module 310, and images of the first reflected beam L11 and the second transmitted beam L22 may be superimposed without being inverted to form the first mixed beam MB1.

As the first transmitted beam L12 and the second reflected beam L21 pass through the inversion module 310, images of the first transmitted beam L12 and the second reflected beam L21 may be vertically and horizontally inverted. The first transmitted beam L12 and the second reflected beam L21 that are vertically and horizontally inverted may be superimposed on each other to form the second mixed beam MB2.

In the illustrated embodiment, the intensity of the first mixed beam MB1 may be substantially the same as that of the second mixed beam MB2.

When the intensity of the first incident laser beam L1 is A and the intensity of the second incident laser beam L2 is B, because the first mixed beam MB1 is obtained by superimposing the first reflected beam L11 and the second transmitted beam L22, the intensity of the first mixed beam MB1 is A/2+B/2. Similarly, because the second mixed beam MB2 is obtained by superimposing the first transmitted beam L12 and the second reflected beam L21, the intensity of the second mixed beam MB2 is A/2+B/2. This means that even when the first incident laser beam L1 and the second incident laser beam L2 have different intensities, the first mixed beam MB1 and the second mixed beam MB2 of the illustrated embodiment have substantially the same intensity.

The first mixed beam MB1 and the second mixed beam MB2 may finally be superimposed on each other to form an output mixed beam MB. The first mixed beam MB1 may have a pulse shape with high intensity on upper and left sides, similar to the first incident laser beam L1 and the second incident laser beam L2. Because the second mixed beam MB2 is obtained by vertically and horizontally inverting the images of the first incident laser beam L1 and the second incident laser beam L2, the second mixed beam MB2 may have a pulse shape with high intensity on lower and upper sides. Accordingly, the output mixed beam MB may have a pulse shape in which the intensities of upper, lower, left, and right sides are uniform throughout.

The homogenizer 500 may be arranged on an optical path of a laser beam having passed through the beam mixer 300. The homogenizer 500 may include a first homogenizer array 501 and a second homogenizer array 502 that are apart from each other. The homogenizer 500 may separate an incident laser beam into a plurality of laser beams, so that the intensity distribution of the laser beam may be uniform in a two-dimensional space.

The condenser lens 600 may be arranged on an optical path of a laser beam having passed through the homogenizer 500. The condenser lens 600 may adjust the size and focus of the laser beam having passed through the homogenizer 500 to form a laser beam LB that is linear.

This means that the laser beam LB incident on an amorphous silicon layer is formed linearly and has a uniform intensity distribution in a region of the amorphous silicon layer, which is irradiated with the laser beam LB. As a result, a polysilicon layer formed after crystallization of the amorphous silicon layer may have uniform characteristics at various points.

The optical system 200 may further include a telescope lens (not shown) arranged between the beam mixer 300 and the homogenizer 500. The telescope lens may enlarge the laser beam having passed through the beam mixer 300 to form a beam having a desired size.

In addition, the optical system 200 may further include a plurality of mirrors for adjusting a path, a plurality of lenses for adjusting a size and focus, or the like.

Although FIG. 3A shows that the components in the optical system 200 or the inversion module 310 are two-dimensionally arranged, the components in the optical system 200 or the inversion module 310 may be three-dimensionally arranged.

Referring to FIG. 3B, the inversion module 310 may include the first to fifth mirrors MR1 to MR5 that are three-dimensionally arranged. A laser beam incident on the inversion module 310 may be incident in a +x direction (also referred to as a first direction). The first mirror MR1 may change a path of the laser beam to a +z direction (also referred to as a second direction). The second mirror MR2 may be apart from the first mirror MR1 in the +z direction. The second mirror MR2 may change the path of the laser beam to the +x direction. The third mirror MR3 may be apart from the second mirror MR2 in the +x direction. The third mirror MR3 may change the path of the laser beam to a −z direction. The fourth mirror MR4 may be apart from the third mirror MR3 in the −z direction. The fifth mirror MR5 may change the path of the laser beam to a +y direction (also referred to as a third direction). An image of the laser beam having passed through the inversion module 310 may be vertically and horizontally inverted at the same time as the path of the laser beam is changed. The arrangement shown in FIG. 3B is an example, and the arrangement of the mirrors in the inversion module 310 may vary depending on an optical path.

The beam mixer 300 in embodiments may implement a high-quality polysilicon layer with a simple structure.

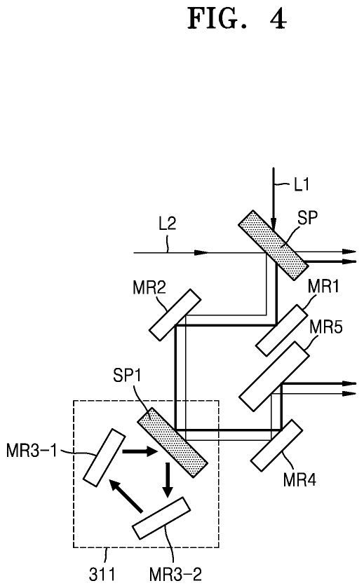

FIG. 4 shows an embodiment of the beam mixer 300 (refer to FIGS. 2 and 3A). In FIG. 4, the same reference numerals as those in FIG. 3A denote the same components.

Referring to FIG. 4, the beam mixer 300 includes the splitter SP and the inversion module 310 (refer to FIGS. 3A and 3B), the splitter SP being arranged at a front end of an optical path. The inversion module 310 may include a plurality of mirrors, and may vertically and horizontally invert an image of a laser beam. A laser beam passing through the beam mixer 300 may include the first mixed beam MB1 (refer to FIGS. 3A and 3B) in which an image of a laser beam is not inverted, and the second mixed beam MB2 (refer to FIGS. 3A and 3B) in which an image of a laser beam is inverted.

In the illustrated embodiment, the inversion module 310 may include a circulation module 311 that increases an optical path. The circulation module 311 may be arranged between the second mirror MR2 and the fourth mirror MR4. The circulation module 311 may include a first splitter SP1, a third-first mirror MR3-1, and a third-second mirror MR3-2. A portion of a laser beam having passed through the second mirror MR2 may have an increased optical path while passing through the circulation module 311. Accordingly, a pulse period of the laser beam may increase.

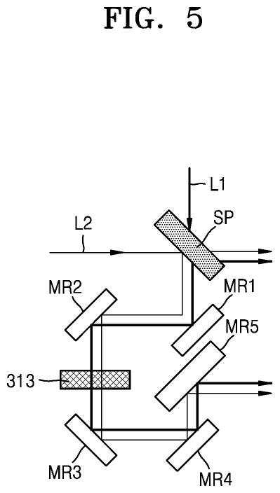

FIG. 5 shows an embodiment of the beam mixer 300 (refer to FIGS. 2 and 3A). In FIG. 5, the same reference numerals as those in FIG. 3A denote the same components.

Referring to FIG. 5, the beam mixer 300 includes the splitter SP and the inversion module 310 (refer to FIGS. 3A and 3B), the splitter SP being arranged at a front end of an optical path. The inversion module 310 may include a plurality of mirrors, and may vertically and horizontally invert an image of a laser beam. A laser beam passing through the beam mixer 300 may include the first mixed beam MB1 (refer to FIGS. 3A and 3B) in which an image of a laser beam is not inverted, and the second mixed beam MB2 (refer to FIGS. 3A and 3B) in which an image of a laser beam is inverted.

In the illustrated embodiment, the inversion module 310 may further include an optical member 313. The optical member 313 may be a polarizing plate, an optical filter, a light attenuator, or the like. The optical member 313 may be arranged between the second mirror MR2 and the third mirror MR3. In an alternative embodiment, the optical member 313 may have various modifications, such as being arranged between the first mirror MR1 and the second mirror MR2 or between the third mirror MR3 and the fourth mirror MR4.

When the optical member 313 is a polarization plate, the optical member 313 may select a desired polarization state from among polarization states of incident laser beams. In some embodiments, the optical member 313 may improve superimposition characteristics by making polarization of the incident laser beams constant.

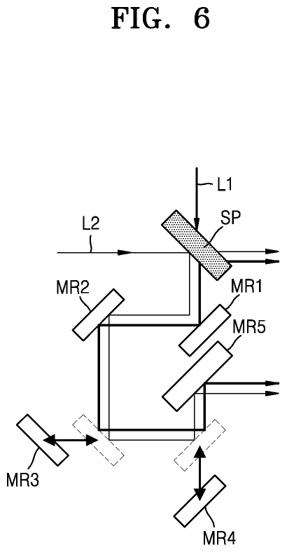

FIG. 6 shows an embodiment of the beam mixer 300 (refer to FIGS. 2 and 3A). In FIG. 6, the same reference numerals as those in FIG. 3A denote the same components.

Referring to FIG. 6, the beam mixer 300 includes the splitter SP and the inversion module 310 (refer to FIGS. 3A and 3B), the splitter SP being arranged at a front end of an optical path. The inversion module 310 may include a plurality of mirrors, and may vertically and horizontally invert an image of a laser beam. A laser beam passing through the beam mixer 300 may include the first mixed beam MB1 (refer to FIGS. 3A and 3B) in which an image of a laser beam is not inverted, and the second mixed beam MB2 (refer to FIGS. 3A and 3B) in which an image of a laser beam is inverted.

In the illustrated embodiment, at least some of the plurality of mirrors included in the inversion module 310 may be moving mirrors. In an embodiment, the third mirror MR3 may be a moving mirror that may be horizontally moved, for example. The fourth mirror MR4 may be a moving mirror that may be vertically moved. The moving mirror may serve as a beam shifter. As the plurality of mirrors included in the inversion module 310 is provided as moving mirrors, a path of a laser beam may be more precisely controlled.

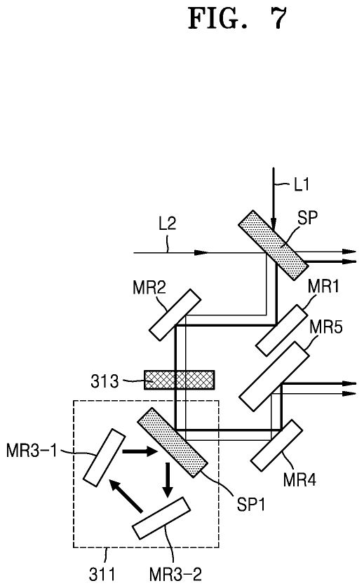

FIG. 7 shows an embodiment of the beam mixer 300 (refer to FIGS. 2 and 3A). In FIG. 7, the same reference numerals as those in FIGS. 3A to 6 denote the same components.

Referring to FIG. 7, the beam mixer 300 includes the splitter SP and the inversion module 310 (refer to FIGS. 3A and 3B), the splitter SP being arranged at a front end of an optical path. The inversion module 310 may include a plurality of mirrors, and may vertically and horizontally invert an image of a laser beam. A laser beam passing through the beam mixer 300 may include the first mixed beam MB1 (refer to FIGS. 3A and 3B) in which an image of a laser beam is not inverted, and the second mixed beam MB2 (refer to FIGS. 3A and 3B) in which an image of a laser beam is inverted.

In the illustrated embodiment, the inversion module 310 may include the circulation module 311, the optical member 313, and the fourth mirror MR4 that is provided as a moving mirror. The circulation module 311 may include the first splitter SP1, the third-first mirror MR3-1, and the third-second mirror MR3-2. A portion of a laser beam having passed through the second mirror MR2 may have an increased optical path while passing through the circulation module 311. The optical member 313 may be a polarizing plate, an optical filter, a light attenuator, or the like. Accordingly, the inversion module 310 may vertically and horizontally invert an image of the laser beam at the same time as finely adjusting an optical path, light intensity, or the like thereof.

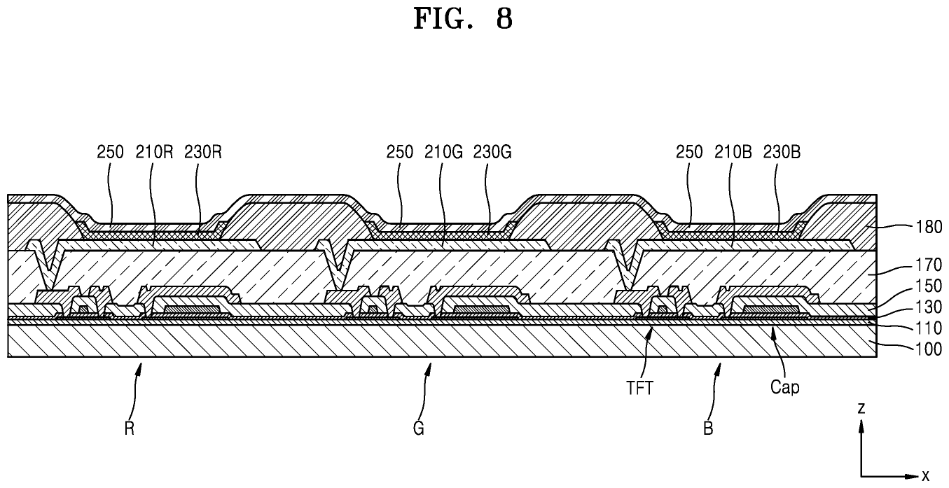

Although a laser beam annealing apparatus has been described above, the disclosure is not limited thereto. In an embodiment, a method of manufacturing a display apparatus by the laser beam annealing apparatus as described above also falls within the scope of the disclosure, for example. FIG. 8 is a cross-sectional view schematically illustrating a portion of an organic light-emitting display apparatus as a display apparatus manufactured according to the manufacturing method.

Common layers, such as a buffer layer 110, a gate insulating layer 130, and an inter-insulating layer 150 may be formed or disposed on a substrate 100 over the entirety of the surface of the substrate 100, and a semiconductor layer including polysilicon may also be formed or disposed on the substrate 100. In addition, a thin-film transistor TFT including the semiconductor layer, a gate electrode, a source electrode, and a drain electrode may be formed or disposed on the substrate 100.

To form the thin-film transistor TFT, an amorphous silicon layer is formed or disposed on the substrate 100, and the amorphous silicon layer on the substrate 100 is annealed into a polysilicon layer by the laser beam annealing apparatus described above. In addition, a plurality of thin-film transistors TFT may be formed by patterning the polysilicon layer and forming gate electrodes, source electrodes, and drain electrodes. When forming the thin-film transistors TFT, a capacitor Cap or wiring may be simultaneously formed using the same material as that of the thin-film transistors TFT.

In addition, a planarization layer 170 covering the thin-film transistor TFT and including a substantially flat upper surface is formed or disposed over the entirety of the surface of the substrate 100. Organic light-emitting devices electrically and respectively connected to the plurality of thin-film transistors TFT are formed or disposed on the planarization layer 170. The organic light-emitting devices may include pixel electrodes 210R, 210G, and 210B that are patterned, an opposite electrode 250 that substantially corresponds to the entirety of the surface of the substrate 100, and intermediate layers 230R, 230G, and 230B that are arranged between the pixel electrodes 210R, 210G, and 210B and the opposite electrode 250 and each have a multi-layer structure including an emission layer. Unlike the intermediate layers 230R, 230G, and 230B that are patterned to respectively correspond to the pixel electrodes 210R, 210G, and 210B, layers, such as a hole injection layer (“HIL”), a hole transport layer (“HTL”), and an electron transport layer (“ETL”), may be common layers that substantially correspond to the entirety of the surface of the substrate 100, and some other layers, such as an emission layer, may be layers that are patterned to respectively correspond to the pixel electrodes 210R, 210G, and 210B. The pixel electrodes 210R, 210G, and 210B may be electrically and respectively connected to the thin-film transistors TFT through via holes. A pixel-defining layer 180 which covers edges of the pixel electrodes 210R, 210G, and 210B and in which an opening defining each pixel region is defined may be formed or disposed on the planarization layer 170 to substantially correspond to the entirety of the surface of the substrate 100.

In manufacturing the organic light-emitting display apparatus including a red sub-pixel R, a green sub-pixel G, and/or a blue sub-pixel B as described above, a semiconductor layer including a polysilicon layer may be formed by the laser beam annealing apparatus in the embodiments described above.

The scope of the disclosure may include the method of manufacturing a display apparatus described above in which an amorphous silicon layer is formed or disposed on the substrate 100, the amorphous silicon layer is converted into a polysilicon layer by irradiation with a laser beam emitted from the laser beam annealing apparatus according to at least one of the embodiments described above, and then, a display element is formed. Because the display apparatus manufactured as described above allows uniform grains to be generated in a laser beam annealing process during the manufacture thereof, the thin-film transistors TFT in various positions may have uniform electrical characteristics, and thus, a high-quality display apparatus may be implemented.

The disclosure is not limitedly applied to an organic light-emitting display apparatus. In an embodiment, the scope of application of the disclosure may include any display apparatus, such as a liquid crystal display apparatus, that includes a thin-film transistor including a polysilicon layer as a semiconductor layer, for example.

The laser beam annealing apparatus in embodiments may implement a high-quality polysilicon layer with a simple structure.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A laser beam annealing apparatus comprising:
a laser generator which generates a first incident laser beam and a second incident laser beam;
a beam mixer arranged on optical paths of the first incident laser beam and the second incident laser beam and comprising an inversion module which vertically and horizontally inverts an image of a laser beam;
a homogenizer arranged on an optical path of a laser beam having passed through the beam mixer; and
a condenser lens arranged on an optical path of a laser beam having passed through the homogenizer,
wherein the laser beam having passed through the beam mixer comprises a first mixed beam in which an image is not inverted and a second mixed beam in which an image is vertically and horizontally inverted.

2. The laser beam annealing apparatus of claim 1, wherein the beam mixer further comprises a splitter arranged at a front end of the inversion module.

3. The laser beam annealing apparatus of claim 1, wherein the inversion module comprises a plurality of mirrors, at least one of the plurality of mirrors vertically inverts an image of a laser beam, and at least one of the plurality of mirrors horizontally inverts an image of a laser beam.

4. The laser beam annealing apparatus of claim 1, wherein the inversion module comprises a first mirror, a second mirror, a third mirror, a fourth mirror, and a fifth mirror which are apart from each other and sequentially arranged along the optical path.

5. The laser beam annealing apparatus of claim 4, wherein a laser beam incident on the first mirror is incident in a first direction, the second mirror is arranged apart from the first mirror in a second direction perpendicular to the first direction, and a laser beam emitted through the fifth mirror is emitted in a third direction perpendicular to the first and second directions.

6. The laser beam annealing apparatus of claim 4, wherein the inversion module further comprises a circulation module which is arranged between the second mirror and the third mirror and increases the optical path.

7. The laser beam annealing apparatus of claim 4, wherein the inversion module further comprises an optical member arranged between the second mirror and the third mirror.

8. The laser beam annealing apparatus of claim 7, wherein the optical member comprises a polarizing plate.

9. The laser beam annealing apparatus of claim 4, wherein the third mirror and the fourth mirror comprise moving mirrors.

10. The laser beam annealing apparatus of claim 1, wherein the inversion module comprises a circulation module, an optical member, and a moving mirror, and
the circulation module increases the optical path.

11. A method of manufacturing a display apparatus, the method comprising:
forming an amorphous silicon layer on a substrate;
annealing the amorphous silicon layer on the substrate into a polysilicon layer by a laser beam annealing apparatus;
forming a plurality of thin-film transistors by patterning the polysilicon layer; and
forming display elements electrically and respectively connected to the plurality of thin-film transistors,
wherein the laser beam annealing apparatus comprises:
a laser generator which generates a first incident laser beam and a second incident laser beam;
a beam mixer arranged on optical paths of the first incident laser beam and the second incident laser beam and comprising an inversion module which vertically and horizontally inverts an image of a laser beam;
a homogenizer arranged on an optical path of a laser beam having passed through the beam mixer; and
a condenser lens arranged on an optical path of a laser beam having passed through the homogenizer.

12. The method of claim 11, wherein the beam mixer of the laser beam annealing apparatus further comprises a splitter arranged at a front end of the inversion module.

13. The method of claim 11, wherein the inversion module of the laser beam annealing apparatus comprises a plurality of mirrors, at least one of the plurality of mirrors vertically inverts an image of a laser beam, and at least one of the plurality of mirrors horizontally inverts an image of a laser beam.

14. The method of claim 11, wherein the inversion module of the laser beam annealing apparatus comprises a first mirror, a second mirror, a third mirror, a fourth mirror, and a fifth mirror which are apart from each other and sequentially arranged along the optical path.

15. The method of claim 14, wherein a laser beam incident on the first mirror is incident in a first direction, the second mirror is arranged apart from the first mirror in a second direction perpendicular to the first direction, and a laser beam emitted through the fifth mirror is emitted in a third direction perpendicular to the first and second directions.

16. The method of claim 14, wherein the inversion module further comprises a circulation module which is arranged between the second mirror and the third mirror and increases the optical path.

17. The method of claim 14, wherein the inversion module further comprises an optical member arranged between the second mirror and the third mirror.

18. The method of claim 17, wherein the optical member comprises a polarizing plate.

19. The method of claim 14, wherein the third mirror and the fourth mirror comprise moving mirrors.

20. The method of claim 11, wherein the inversion module of the laser beam annealing apparatus comprises a circulation module, an optical member, and a moving mirror, and
the circulation module increases the optical path.
